(19) United States
(12) Patent Application Publication
(10) Pub. No.: US 2003/0122133 A1
(43) Pub. Date: Jul. 3, 2003

(54) Semiconductor device using single carbon nanotube and method of manufacturing of the same

(76) Inventors: Sung Yool Choi, Daejon-Shi (KR); Yong Sung Yoon, Daejon-Shi (KR); Seong Deok Ahn, Daejon-Shi (KR); Yoon Ho Song, Daejon-Shi (KR); Jin Ho Lee, Daejon-Shi (KR); Kyoung Ik Cho, Daejon-Shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/152,219

(22) Filed: May 20, 2002

(30) Foreign Application Priority Data
Dec. 28, 2001 (KR) 2001-86832

(51) Int. Cl. H01L 31/0312

(52) U.S. Cl. 257/77

(57) ABSTRACT

The present invention relates to a semiconductor device using a single carbon nanotube and a method of manufacturing the same. In a process of manufacturing a bipolar transistor using a p-n junction, a given region of a single carbon nanotube of a N type is exposed by means of a common semiconductor manufacturing process and the exposed portion of a carbon nanotube of a P type is then made to be a carbon a single carbon nanotube of a N type by means of a doping process, thus forming a P-N-P or N-P-N bipolar transistor. Therefore, the present invention can improve the integration degree and the operating speed of the device.

### BACKGROUND OF THE INVENTION

1. Field of the Invention

The invention relates generally to a semiconductor device using single carbon nanotube and a method of manufacturing the same, and more particularly to, a semiconductor device using single carbon nanotube, by use of semiconductor carbon nanotube capable of controlling the flow of electrons as an electron channel, and a method of manufacturing the same.

2. Description of the Prior Art

A bipolar transistor is a representative semiconductor device using a p-n junction. The transistor is a switching device for controlling the flow of current by forming two p-n junctions such as a P-N-P type or a N-P-N type.

If the bipolar transistor is fabricated by a conventional method of manufacturing a Si semiconductor, the operating characteristic is good but the integration degree is low and the power consumption is high compared to that of CMOS device. Therefore, the method could be rarely applied to a method of manufacturing a logic device or a memory device. If the transistor is fabricated using nano materials such as carbon nanotube, and the like, however,. the integration degree and the operating speed could be significantly improved and the power consumption could be reduced.

The switching device using carbon nanotube that have been developed so far includes CNTFET proposed by Avourios group in IBM Co., Intramolecular p-n junction proposed by Dekker group, and the like.

CNTFET is a field effect transistor (FET) that uses carbon nanotube as an electron channel material instead of conventional doped silicon. CNTFET could not have been implemented so far because an n-channel FET and a p-channel FET are separately formed.

Intramolecular p-n junction has a P type in one side of one strip of the carbon nanotube and an N type in the other side of it by generating a structural defect in one strip of carbon nanotube. However. it is not practical because the location of the defect could not be controlled.

### SUMMARY OF THE INVENTION

The present invention is contrived to solve the above problems and an object of the present invention is to provide a semiconductor device using single carbon nanotube and a method of manufacturing the same, capable of improving the integration degree and the operating speed, in such a way that a given region of a P type single carbon nanotube is exposed by a common semiconductor manufacturing process, and the exposed portion of the P type carbon nanotube is then made to be a N type single carbon nanotube by a doping process to produce a P-N-P or N-P-N bipolar transistor.

In order to accomplish the above object, a semiconductor device using a single carbon nanotube according to the present invention, is characterized in that it comprises a first carbon nanotube having one doping type, and a p-n junction made of a second carbon nanotube having the opposite doping type to said one doping type of said first carbon nanotube in a predetermined region.

A semiconductor device using a single carbon nanotube according to the present invention, is characterized in that it comprises an emitter and a collector made of a first single carbon nanotube having one doping type, and a base made of a second single carbon nanotube having the opposite doping type to said one doping type of said first single carbon nanotube.

A method of manufacturing a semiconductor device using a single carbon nanotube according to the present invention, is characterized in that it comprises the step of forming a single carbon nanotube and the step of converting a predetermined region of said single carbon nanotube into an opposite doping type of said single carbon nanotube by means of a doping process, in order to form a p-n junction.

A method of manufacturing a semiconductor device using a single carbon nanotube according to the present invention, is characterized in that it comprises the step of forming a single carbon nanotube and the step of converting a predetermined region of said single carbon nanotube into an opposite doping type of said single carbon nanotube by means of a doping process, in order to form a bipolar transistor.

In the above, the single carbon nanotube of an opposite type is formed by doping oxygen or alkali metal at the region of the single carbon nanotube.

### BRIEF DESCRIPTION OF THE DRAWINGS

The aforementioned aspects and other features of the present invention will be explained in the following description, taken in conjunction with the accompanying drawings, wherein:

FIG. 1 is a typical molecule structure of carbon nanotube;

FIG. 2 is a layout diagram of a semiconductor device using a carbon a single carbon nanotube according to one embodiment of the present invention;

FIG. 3a and FIG. 3b are cross-sectional views of the layout shown in FIG. 2 taken along lines A-A′; and

FIG. 4a- FIG. 4e are cross-sectional views of a semiconductor device using a carbon a single carbon nanotube for explaining a method of manufacturing the device according to one embodiment of the present invention.

### DETAILED DESCRIPTION OF PREFERRED EMBODIMENTS

The present invention will be described in detail by way of a preferred embodiment with reference to accompanying drawings.

The molecule structure and property of a general carbon nanotube will be first described.

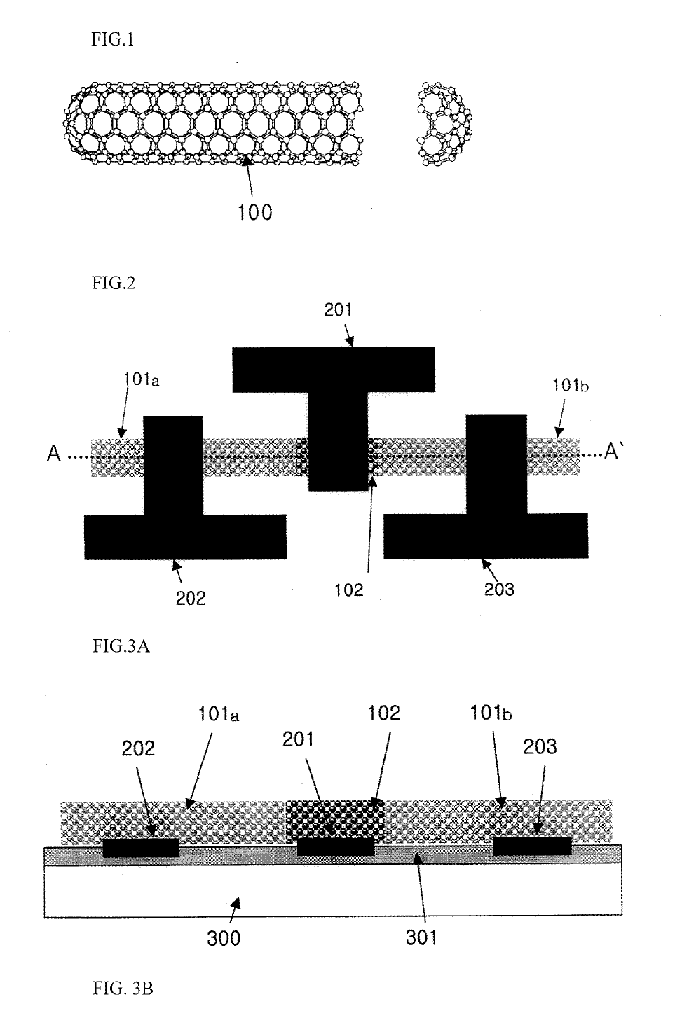

FIG. 1 is a typical molecule structure of a carbon nanotube.

Referring now to FIG. 1, the carbon nanotube 100 has carbon atoms along the surface of the cylindrical shape and has a hemi-spherical shape in its end portion. The carbon nanotube 100 has a metallic or semiconductor property depending on the number of carbon atoms constituting the cylindrical shape and the coupling direction of them. Therefore, the carbon nanotube 100 may be employed as a nano conductor or a semiconductor in an axial direction.

In the present invention, a semiconductor carbon nanotube capable of controlling the flow of electrons is used as an electron channel.

The carbon nanotube 100 is a metal or semiconductor of a nanometer size and can have the doping effect through a simple process. Thus, a bipolar transistor of a nanometer size can be fabricated using a single strip of carbon nanotube.

A structure of a semiconductor device using a single carbon nanotube according to the present invention will be below described.

FIG. 2 is a layout diagram of a semiconductor device using a single carbon nanotube according to one embodiment of the present invention, and FIG. 3a and FIG. 3b are cross-sectional views of the layout shown in FIG. 2 taken along lines A-A′.

Referring now to FIG. 2 and FIG. 3a, a single carbon nanotube bipolar transistor on a substrate 300 includes an emitter 101a of a P type carbon nanotube, a collector 101b of a P type carbon nanotube, and a base 102 of an N type carbon nanotube. An emitter electrode 202 is formed in the emitter 101a, a collector electrode 203 is formed in the collector 101b and a base electrode 201 is formed in the base 102. The single carbon nanotube bipolar transistor is connected to peripheral circuits or other transistors through electrodes 201˜203 which are each isolated by an insulating layer 301, thus forming an electron circuit.

The single carbon nanotube having the semiconductor property has naturally a p-type semiconductor property. Therefore, if a single carbon nanotube at a portion where the base 102 will be formed is doped with a n-type, the base 102 made of a N type carbon nanotube is formed to produce a p-n-P type bipolar transistor.

At this case, if oxygen (O₂) or alkali metals (i.e., K) is doped into the naturally P type single carbon single nanotube, the doped portion changes to an N type carbon nanotube. Therefore, in order to change only a desired portion of one strip of single carbon nanotube to a N type, the doping of oxygen (O₂) or alkali metals (i.e., K) should be prevented by forming a protection layer at remaining portions.

Above-mentioned case describes that-the P-N-P type bipolar transistors where the emitter 101a and the collector 101b are formed with a P type carbon nanotube and the base 102 is formed with a N type carbon nanotube.

Meanwhile, if the regions where oxygen (O₂) or alkali metals (i.e., K) have the opposite type to doping in the P-N-P type bipolar transistor, a N-P-N type bipolar transistor may be manufactured, as shown in FIG. 3b.

At this case, the length of the P type carbon nanotube or the N type carbon nanotube constituting the base is very important in determining the operating speed and current density of the transistor. As shorter the length, faster the operating speed. It facilitates the movement of electrons and thus makes faster the switching speed, thus allowing manufacturing of a higher-integration and higher-speed device.

A method of manufacturing a single carbon nanotube bipolar transistor according to one embodiment of the present invention will be below described.

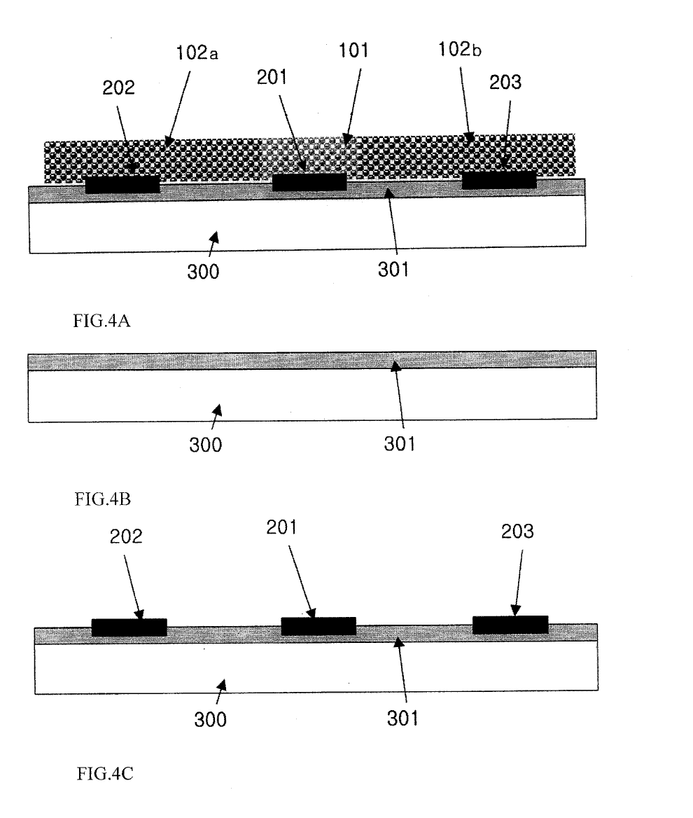

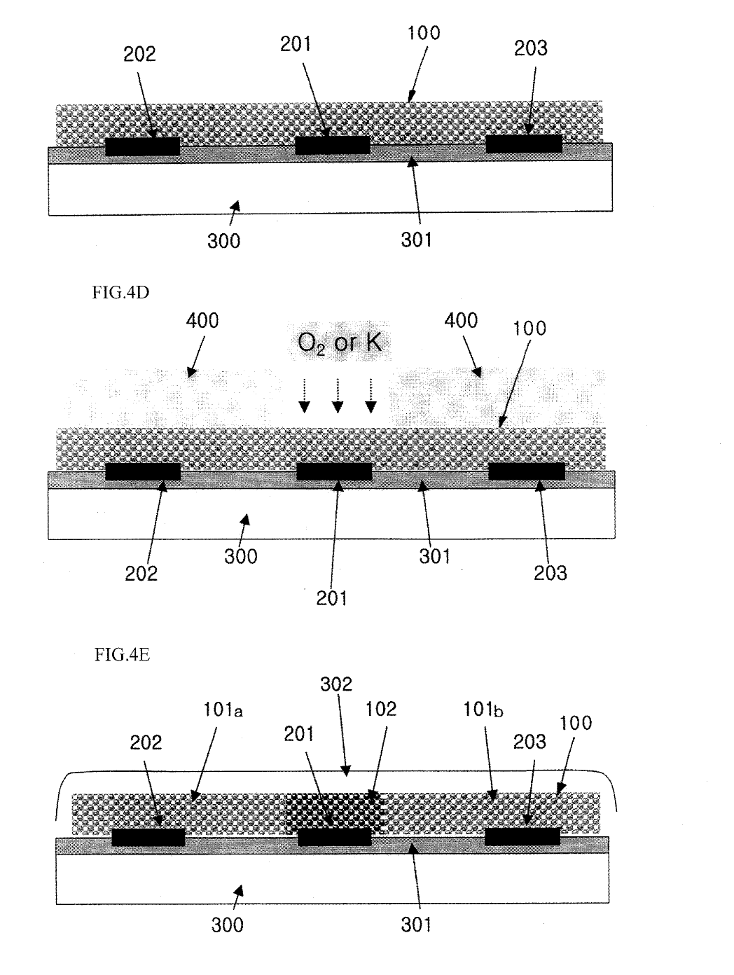

FIG. 4a˜FIG. 4e are cross-sectional views of a semiconductor device using a carbon a single carbon nanotube for explaining a method of manufacturing the device according to one embodiment of the present invention.

Referring now to FIG. 4a) an insulating layer 301 is deposited on a substrate 300. The insulating layer 301 serves to isolate electrons that will be formed in a subsequent process and also to isolate the substrate 300 and carbon nanotube that will be formed in a subsequent process.

Referring now to FIG. 4b, a base electrode 201, an emitter electrode 202 and a collector electrode 203 are formed on the insulating layer 301.

Each of the electrodes 201˜203 is formed by lithography and metal deposition methods.

Referring now to FIG. 4c, carbon nanotube 100 is formed on given regions including the surfaces of respective electrodes 201˜203. The carbon nanotube 100 is formed to be a bundle of one strip or more than one strips. The carbon nanotube horizontally grown or grown in advance is formed by a method distributing it over the substrate.

The carbon nanotube for which the doping process is basically not performed after deposition has a P type semiconductor characteristic. Therefore, in order to make the carbon nanotube 100 be an N type semiconductor, a predetermined doping process should be performed.

If a p-n-p bipolar transistor is to be manufactured, it is required that the carbon nanotube 100 at a region where the base will be formed should be changed to be an N type. At this time, oxygen or alkali metal is doped into the P type carbon nanotube to form an N type carbon nanotube. Therefore, oxygen or alkali metal is doped into the carbon nanotube 100 at a region where the base will be formed, thus forming the P-N-P bipolar transistor.

A method of forming the N type carbon nanotube by doping oxygen or alkali metals into the carbon nanotube 100 at a region where the base will be formed will be below described.

Referring now to FIG. 4d, a protection layer 400 is formed on a region where an emitter and a collector will be formed to expose only the carbon nanotube 100 at a region where a base will be formed. Next, the carbon nanotube 100 is experienced by an annealing process for under oxygen atmosphere at the temperature of 100˜250° C. or is exposed to an alkali metal such as K, so that the p type carbon nanotube 100 is changed to the n type carbon nanotube. Thereafter, the protection layer 400 is removed.

The carbon nanotube exposed to oxygen or alkali metal has a high density of electrons that could be relatively moved freely around a conduction band. Due to this phenomenon, electrons can be a major carrier. Therefore, the p type carbon nanotube 100 changes to a n type.

Referring now to FIG. 4d, the base 102 made of a n type carbon nanotube is formed on the base electrode 201 by means of a doping process. The emitter 101a and the collector 101b of a normal p type carbon nanotube are each formed on the emitter electrode 202 and the collector electrode 203, thereby a p-n-p bipolar transistor carbon nanotube is manufactured.

Referring now to FIG. 4e, a capping layer 302 for protecting respective components is formed on the entire structure.

In the method of manufacturing the above mentioned single carbon nanotube bipolar transistor, it describes that the protection layer 400 is formed only on the emitter and collector regions to expose the carbon nanotube in the base region, and thus the carbon nanotube in the base region becomes a n type so that a p-n-p bipolar transistor is manufactured. In case of the n-p-n bipolar transistor, however, it should be noted that the protection layer 400 is formed only on the base region to expose the carbon nanotube at the emitter and collector regions and thus the carbon nanotube at the emitter and collector region becomes a n type, so that the n-p-n the bipolar transistor is manufactured.

Meanwhile, though, the carbon nanotube 100 is formed after the electrodes 201˜203 are formed in above-mentioned manufacturing method, it should be noted that the carbon nanotube 100 may be first deposited on the substrate 300 and the electrodes 201˜203 may be formed on the carbon nanotube 100 after a doping process in another process. Preferably, the electrodes 201˜203 are formed in view of the process.

As mentioned above, the present invention can change a portion of carbon nanotube to an N type through a simple doping process. Therefore, nano electron devices can be easily manufactured and a transistor to switching-operated at a room temperature can be constituted due to molecular electron devices. Thus, the present invention has outstanding advantages that it can have significant increases in the integration degree compared to a prior art, since the circuit is constituted using a bipolar transistor using a single carbon nanotube and be able to be operated in a high speed.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed is:

1. A semiconductor device using a single carbon nanotube, comprising:
a first carbon nanotube having one doping type; and
a p-n junction made of a second carbon nanotube having the opposite doping type to said one doping type of said first carbon nanotube in a predetermined region.

2. The semiconductor device claimed in claim 1, wherein said second carbon nanotube having the opposite doping type to said one doping type of said first carbon nanotube is doped with oxygen or alkali metal.

3. The semiconductor device claimed in claim 2, wherein said alkali metal is K

4. A semiconductor device using a single carbon nanotube, comprising:
an emitter and a collector made of a first single carbon nanotube having one doping type; and
a base made of a second single carbon nanotube having the opposite doping type to said one doping type of said first single carbon nanotube.

5. The semiconductor device claimed in claim 4, wherein said second single carbon nanotube having the opposite doping type to said one doping type of said first carbon nanotube is doped with oxygen or alkali metal.

6. The semiconductor device claimed in claim 5, wherein said alkali metal is K

7. A method of manufacturing a semiconductor device using a single carbon nanotube, comprising the steps of:
forming a single carbon nanotube; and
converting a predetermined region of said single carbon nanotube into an opposite doping type of said single carbon nanotube by means of a doping process, in order to form a p-n junction.

8. The method claimed in claim 7, wherein the method further comprises the step of forming electrodes with a given pattern below said single carbon nanotube.

9. The method claimed in either claim 7 , wherein said single carbon nanotube of an opposite type is formed by doping oxygen or alkali metal at the re i on of said single carbon nanotube.

10. The method claimed in claim 8, wherein said oxygen is doped at the given region of said single carbon nanotube by an annealing process under an oxygen atmosphere at the temperature of 100˜250° C.

11. The method claimed in claim 5, wherein said alkali metal is K

12. A method of manufacturing a semiconductor device using a single carbon nanotube, comprising the steps of:
forming a single carbon nanotube; and
converting a predetermined region of said single carbon nanotube into an opposite doping type of said single carbon nanotube by means of a doping process, in order to form a bipolar transistor.

13. The method claimed in claim 12, wherein the method further comprises the step of forming electrodes with a given pattern below said single carbon nanotube.

14. The method claimed in either claim 12, wherein said single carbon nanotube of an opposite type is formed by doping oxygen or alkali metal at the region of said single carbon nanotube.

15. The method claimed in claim 14, wherein said oxygen is doped at the given region of said single carbon nanotube by an annealing process under an oxygen atmosphere at the temperature of 100˜250° C.

16. The method claimed in claim 14, wherein said alkali metal is K
